(19) United States
(12) Patent Application Publication
(10) Pub. No.: US 2015/0364536 A1
(43) Pub. Date: Dec. 17, 2015

(54) DEVICE COMPRISING A PLURALITY OF THIN LAYERS

(71) Applicants: THALES, Courbevoie (FR); CENTRE NATIONAL DE LA RECHERCHE SCIENTIFIQUE (C.N.R.S.), Paris (FR); Universite Paris-Sud, Orsay (FR)

(72) Inventors: Manuel Bibes, Paris (FR); Agnes Barthelemy, Janvry (FR)

(21) Appl. No.: 14/415,992

(22) PCT Filed: Jul. 19, 2013
(86) PCT No.: PCT/EP2013/065278

§ 371 Date: Aug. 7, 2015

(30) Foreign Application Priority Data
Jul. 20, 2012 (FR) 12 02071

(51) Int. Cl. H01L 49/02; H01L 49/00; H01L 27/115; G11C 11/22; G11C 11/56

(52) U.S. Cl. CPC H01L 28/55; G11C 11/221; G11C 11/2275; G11C 11/5657; H01L 27/11507; H01L 49/003

(57) ABSTRACT

The invention relates to a device (10) including a plurality of thin layers (12, 14, 18) comprising a layer (14) formed with a polarizable ferroelectric material according to several polarization directions depending on an electric voltage applied to said layer of ferroelectric material, surrounded by a pair of conductive layers (12, 18) forming electrodes. The device of the invention comprises an intermediate layer (16) between said ferroelectric material layer (14) and one of the conductive layers (12, 18), said intermediate layer (16) consisting of a material for which the electronic properties are modified according to the direction of polarization in said adjacent ferroelectric material layout (14). The device for the invention finds particularly advantageous applications as a memory element of a non-volatile memory, as an element of a programmable logic circuit and as a microswitch.

The present invention relates to a device including a plurality of thin layers, belonging to the field of thin layer heterostructures used in microelectronic components, both for storing information and for processing information.

More particularly, the invention is included in the field of random access non-volatile ferroelectric memories (FeRAM).

In the field of non-volatile random access memories (RAM), it would be desirable to have an element with two terminals which may be used for writing and reading information, for non-destructive reading, which may be miniaturized at will, with low consumption of energy upon reading and writing, and having reading and writing times as short as possible, and with very great endurance. Existing technologies do not give the possibility of attaining the whole of the aforementioned features simultaneously.

A promising emerging approach is based on the effect of tunnel electro-resistance observed in three-layer thin heterostructures, consisting of two conductive layers forming separate electrodes of a thin layer in insulating ferroelectric material used as a tunnel barrier. These heterostructures are known as “ferroelectric tunnel junctions” and are used in FeRAM memories. Below the Curie temperature of the ferroelectric tunnel barrier, remanent polarization may be induced therein. The polarization direction is determined according to the electric field which is applied to the ferroelectric layer. By applying a positive or negative electric voltage greater than a threshold voltage it is possible to modify the polarization direction. Each polarization direction gives the possibility of encoding a piece of information. For example, with two opposite polarization directions, a binary piece of information (0 or 1) may be stored.

In a ferroelectric tunnel junction, the current through the ferroelectric tunnel barrier differs according to the ferroelectric polarization direction, each current corresponding to a tunnel resistance value. This is the tunnel electro resistance effect. The behavior of the ferroelectric junction may be described by the ratio of the tunnel resistances corresponding to different polarization directions, for example, opposite polarization or an “off-on” ratio. The stored piece of information is read by the value of the resistance measured while applying a voltage below the threshold voltage.

In the state of the art, such as for example in patent U.S. Pat. No. 7,759,713 describing a ferroelectric tunnel element and its application as a non-volatile memory element in the field of microelectronics, this ratio attains values between 100 and 1000.

Document US20060145225 describes a ferroelectric memory element (FeRAM) formed with two conductive layers forming electrodes between which are placed a ferroelectric layer for which the polarization direction may be reversed and a non-ferroelectric layer which has the effect of facilitating reading of the polarization, which provides the value of the stored information. In this state of the art, the ratio of tunnel resistances is of the order of 10 to 100.

For certain applications, it is however desirable to obtain a ratio of tunnel resistances much greater than 1,000.

For example, when the ferroelectric tunnel junctions are used as memory points in matrices of the “cross bar arrays” type, the “off-on” ratio should be greater than the number of points of the matrix. In this case, it is of particular interest to obtain an “off-on” ratio much greater than 1,000, in order to allow the integration of a large number of memory points into the matrix.

In the state of the art, another kind of heterostructure is also known formed with electro resistive nanostructures, based on oxides like TiO₂ or SrTiO₃ or on a compound based on Ag and Si. For this type of structures, the “off-on” ratios of more than 10,000 have been reported, as for example mentioned in the article of Jo et al. “High-Density Crossbar Arrays Based on a Si Memristive System” published in Nano Letters 9, pages 870-874, year 2009. However, the different levels of resistance correspond for these heterostructures to different spatial distributions of ions, atoms and of defects such as oxygen voids. Their operation is based on the effect of electro migration of ions or atoms, which involves high operating temperatures and a low operating velocity since it is related to the mobility of ions or atoms.

It is therefore desirable to obtain a device including a plurality of thin layers of the ferroelectric tunnel junction type, having a high tunnel resistance ratio while having a good operating rate.

For this purpose, the invention according to a first aspect, proposes a device including a plurality of thin layers comprising a layer formed with a polarizable ferroelectric material according to several polarization directions according to electric voltage applied to said ferroelectric material layer, surrounded by a pair of conductive layers forming electrodes, characterized in that it comprises an intermediate layer between said ferroelectric material layer and one of the conductive layers, said intermediate layer consisting of a material for which electronic properties are modified according to the direction of polarization in said adjacent layer of ferroelectric material.

The device with thin layers according to the invention forms a ferroelectric tunnel junction with a barrier of variable thickness.

Advantageously, an intermediate layer gives the possibility of amplifying the ratio of tunnel resistances, this intermediate layer being either an additional tunnel barrier or an extension of the adjacent electrode. By means of the characteristic according to which electronic properties of the intermediate layer are modified according to the polarization direction in said adjacent layer of ferroelectric material, in practice, the thickness and/or the average height of the barrier is controlled by the polarization direction. Now, the tunnel current decreases exponentially with the thickness of the barrier, and therefore strong differences in resistance are generated.

Further, as the effect of tunnel electro resistance in the ferroelectric tunnel functions is related to the reversal of the ferroelectric polarization in the barrier, therefore it depends on the atomic positions within each lattice parameter unit of the material forming the tunnel barrier, but none on spatial redistributions of the atoms or of the ions like in the elements based on titanium dixoide TiO₂ or strontium titanate SrTiO₃, much greater operating rates, of the order of one giga Hertz (GHz), may be attained.

The device with thin layers may also have one or several of the features below:
said electronic properties of the intermediate layer are conductivity properties;
said electronic properties of the intermediate layer are a band gap width properties;
modification of the electronic properties of the intermediate layer is obtained by the variation of the carrier density in said intermediate layer;
said intermediate layer consists of a material having a metal-insulator transition depending on the number of carriers;
said intermediate layer consists of a perovskite material from the following: titanium perovskite of formula A₁₋ₓA′ₓTiO₃, wherein A and A′ are different 3+ ions, x varying from 0 to 1; titanium perovskite of formula A₁₋ₓBₓTiO₃, wherein A is a 3+ ion, B is a 2+ ion, x varying between 0 and 1; vanadium perovskite of formula A₁₋ₓBₓVO₃, wherein A is a 3+ ion, B is a 2+ ion, x varying from between 0 and 1; a cobalt perovskite of formula A₁₋ₓBₓCoO₃, wherein A is a 3+ ion, B is a 2+ ion, x varying between 0 and 1; and
the intermediate layer has a thickness comprised between 0.1 nanometers and 10 nanometers.

According to a second aspect, the invention relates to the use of a device such as briefly described above as a memory element of a non-volatile memory, wherein a piece of information is written by applying an electric voltage greater in absolute value to a threshold voltage at the ferroelectric material layer.

According to a third aspect, the invention relates to the use of a device as briefly described above as an element of a programmable logic circuit by applying an electric voltage greater in absolute value than a threshold voltage at the ferroelectric material layer.

According to a fourth aspect, the invention relates to the use of a device as described briefly above as microswitch by applying an electric voltage greater in absolute value than a threshold voltage at the ferroelectric material layer.

Other features and advantages of the invention will become apparent from the description which is given thereof below, as an indication and by no means as a limitation, with reference to the appended figures, wherein:

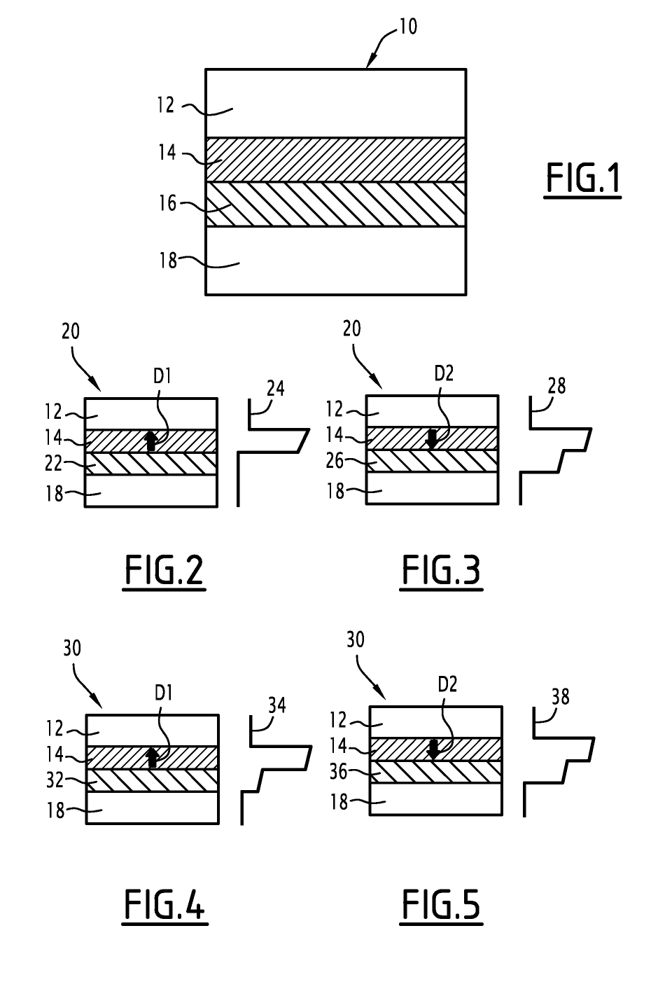

FIG. 1 illustrates a device with thin layers according to the invention;

FIG. 2 illustrates an exemplary device with thin layers with an intermediate conductive layer and an associated potential profile;

FIG. 3 illustrates an exemplary device with thin layers with an intermediate insulating layer and an associated potential profile;

FIG. 4 illustrates an exemplary device with thin layers with an intermediate layer with a small band gap width and an associated potential profile, and

FIG. 5 illustrates an exemplary device with thin layers with an intermediate layer with a strong band gap width and an associated potential profile.

The invention will be described for a device with thin layers forming a ferroelectric tunnel junction, comprising an additional intermediate layer, and its use in a non-volatile memory element, a programmable logic circuit element or a microswitch. Nevertheless, the invention applies similarly with other layouts of layers, for example with two intermediate layers added on either side of the layer forming a ferroelectric tunnel barrier.

FIG. 1 illustrates a device with thin layers forming a ferroelectric tunnel junction 10 according to the invention, consisting of a plurality of layers; a first conductive layer 12, a layer in ferroelectric material forming a ferroelectric tunnel barrier 14, an intermediate thin layer 16, which consists of a material for which the electronic properties are modified according to the direction of polarization in the adjacent ferroelectric layer 14 and a second conductive layer 18. Both conductive layers 12 and 18 positioned at the ends of the element form electrodes.

In the embodiment of FIG. 1, the intermediate layer 16 preferably has a thickness comprised in a range from 0.1 to 10 nanometers (nm), the ferroelectric tunnel barrier layer 14 having a thickness in a range from 0.1 to 10 nanometers also and the electrodes 12, 18 having thicknesses in a range from 0.1 to 500 nm.

In terms of materials used, the electrodes 12, 18 are either metals, or semi-conductors belonging to different families, for example simple metals like Au, Ru or Pt, metal oxides such as SrRuO₃ or (La,Sr)MnO₃, semi-conductors such as Si, GaAs or other III-V compounds (semi-conductors consisting of one or several elements from column III of the periodic table of elements and of one or several elements from column V of this table), semi-conducting oxides such as ZnO, ITO or SrTiO₃, or organic conductors. They may be of type N or of type P.

The ferroelectric tunnel barrier 14 consists of an inorganic ferroelectric material, for example BaTiO₃, Pb(Zr,Ti)O₃, BiFeO₃, SBT, SBN, or an organic ferroelectric material. The electronic properties of the material forming the intermediate thin layer 16 may be modified according to the ferroelectric polarization direction in the adjacent layer.

In an embodiment, such a modification of the electronic properties of the intermediate layer 16 is obtained by varying the carrier density in this layer.

In the preferred embodiment, the material of the intermediate thin layer 16 has a metal-insulator transition depending on the number of carriers, for example a Mott insulator, present in several families of transition metal oxides.

In a non-exhaustive way, the contemplated materials are:
certain nickelates: PrNiO₃, NdNiO₃, SmNiO₃, EuNiO₃, GdNiO₃, TbNiO₃, DyNiO₃, HoNiO₃, ErNiO₃, TmTiO₃, YbNiO₃, LuNiO₃, YNiO₃ or their solid solutions;
certain manganites of the form A₁₋ₓBₓMnO₃ wherein A is a 3+ ion such as La³⁺, Pr³⁺, Nd³⁺, Sm³⁺, Eu³⁺, Gd³+, Tb³⁺, Dy³⁺, Ho³⁺, Er³⁺, Tm³⁺, Yb³⁺, Lu³⁺, Y³⁺ or a 4+ ion such as Ce⁴⁺ and B a 2+ ion such as Ca²⁺, Sr²⁺ or Ba²⁺, x varying between 0 and 1;
certain Ti perovskites of formula:
   A₁₋ₓA′ₓTiO₃, wherein A and A′ are different 3+ ions, A for example being La³⁺ and A′ for example being Y³⁺, Ho³⁺, Er³⁺, Tm³⁺, Yb³⁺, Lu³⁺ , x varying between 0 and 1;
   A₁₋ₓ BₓTiO₃ , wherein A is a 3+ ion such as La³⁺, Pr³⁺, Nd³⁺, Sm³⁺, Eu³⁺, Gd³+, Tb³⁺, Dy³⁺, Ho ³⁺, Er ³⁺, Tm³⁺, Yb ³⁺, Lu³⁺, Y³⁺ and B a 2+ ion such as Ca²⁺, Sr²⁺ or Ba²⁺, x varying between 0 and 1;
certain V perovskites of the form A₁₋ₓBₓVO₃ wherein A is a 3+ ion such as La³⁺, Pr³⁺, Nd³⁺, Sm³⁺, Eu³⁺, Gd³+, Tb³⁺, Dy³⁺, Ho³⁺, Er³⁺, Tm³⁺, Yb³⁺, Lu³⁺, Y³⁺ and B a 2+ ion such as Ca²⁺, Sr²⁺ or Ba²⁺, x varying between 0 and 1;
certain Co perovskites of the form A₁₋ₓBₓCoO₃ wherein A is a 3+ ion such as La³⁺, Pr³⁺, Nd³⁺, Sm³⁺, Eu³⁺, Gd³+, Tb³⁺, Dy³⁺, Ho³⁺, Er³⁺, Tm³⁺, Yb³⁺, Lu³⁺, Y³⁺ and B a 2+ ion such as Ca²⁺, Sr²⁺ or Ba²⁺, x varying between 0 and 1;
certain solid solutions of SrRuO₃ and SrTiO₃;
V oxides such as VO₂ or V₂O₃, optionally doped with Ti or Cr.

Conventionally, a device with thin layers 10 is elaborated by a growth technique or several combined growth techniques, such as pulsed laser ablation, cathode spattering, chemical vapor deposition or evaporation.

The role of the intermediate layer 16 will be more particularly described now in a first embodiment with reference to FIGS. 2 and 3.

In this embodiment, the device with thin layers forming a ferroelectric tunnel junction 20 according to the invention includes an intermediate layer for which the conductivity properties change according to the polarization direction in the adjacent ferroelectric layer.

In the example of FIG. 2, the intermediate layer 16 behaves as a conductive material 22 when the ferroelectric layer 14 is polarized along a first direction D1 illustrated by an arrow. Here, the intermediate layer 22 plays the role of an electrode letting through the current, as illustrated in the schematic potential profile 24 corresponding to the current crossing the device 20: the potential is constant up to a given rated value through the layers 18 and 22, which are both conductive, and then it undergoes a significant variation upon crossing the ferroelectric layer 14 and returns to a value close to the rated value. The potential difference between the layers 12 and 18 is preferentially comprised between 1 and 500 mV.

In the example of FIG. 3, the polarization direction D2 in the ferroelectric layer 14 is opposite to the polarization direction D1 of the example of FIG. 2. The intermediate layer 16 behaves as an insulating material 26, playing the role of an additional tunnel barrier. The electrons then have to cross a composite or hybrid tunnel barrier, formed with the layers 14 and 26, the thickness of which is therefore greater than the thickness of the ferroelectric tunnel barrier 14. The schematic potential profile 28 corresponding to the current crossing the element 20 illustrates this operation: the potential is constant at a given rated value through the conductive layer 18 and then it undergoes a first variation upon crossing the insulating layer 26, and then a second variation upon crossing the ferroelectric layer 14 and returns to a value close to the rated value through the conductive layer 12.

The tunnel current decreases exponentially with the thickness of the barrier. For example, an “off-on” resistance ratio of the order of 1000 or more is attained with the intermediate layer of thickness 2 nm for which the conductivity changes with the polarization of the adjacent ferroelectric layer of thickness 2 nm.

In another embodiment, illustrated in FIGS. 4 and 5, the device with thin layers forming a ferroelectric tunnel junction 30 according to the invention, includes an intermediate layer for which the band gap width varies according to the polymerization direction in the adjacent ferroelectric layer 14. For example, the intermediate layer consists of VO₂

In the example of FIG. 4, when the polymerization direction of the ferroelectric layer 14 is the direction D1, the band gap width of the intermediate layer is small (similar for example to samarium nickelate SmNiO₃), which allows the intermediate layer to behave like a weakly conductive material 32, as this is illustrated in the schematic potential profile 34 corresponding to the current crossing the device 30.

In the example of FIG. 5, the polarization direction D2 in the ferroelectric layer 14 is opposite to the polarization direction D1 of the example of FIG. 4. The intermediate layer 16 behaves as a material 36 with a wide band gap (for example similar to strontium titanate SrTiO₃), thus also playing the role of a tunnel barrier. The schematic potential profile 38 corresponding to the current crossing the device 30 illustrates this operation, which is similar to the operation illustrated in FIG. 3 in which the intermediate layer 16 behaves as an insulating material 26.

Thus, in the embodiment illustrated in FIGS. 4 and 5, the intermediate layer 16 plays a role of an additional tunnel barrier with variable height according to the direction of polarization. In particular, as illustrated in FIG. 5, the thickness of the tunnel barrier is equal to the thickness of the layer 14 plus the thickness of the layer 36, which allows a strong reduction in the tunnel current and therefore an increase in the associated resistance level.

The device with thin layers according to the invention finds a first application as a non-volatile memory element in a memory of the FeRAM type. The piece of information, for example a piece of binary information, is written by applying a voltage which is greater in absolute value than a threshold voltage which is determined depending on the materials making up the various layers, which has the effect of reversing the direction of polarization of the ferroelectric layer. Reversal of the direction of polarization typically allows the storage of a piece of binary information (0 or 1). Once the voltage is cut off, or under the application of a lower voltage, the direction of the polarization is stable. In order to read the stored information, a resistance value is measured upon applying a voltage below the threshold voltage.

The device with thin layers according to the invention defines a second application as an element of a programmable logic circuit, by applying a voltage greater in absolute value than a threshold voltage, in order to write a piece of binary information into the circuit.

The device with thin layers according to the invention finds a third application as a controllable microswitch in a microcircuit intended for logic processing of information, by means of the very high “off-on” tunnel resistance ratio, giving the possibility of making sure that in the “off” state, a negligible current circulates in the circuit controlled by the microswitch, and which may therefore be considered as open.

1. A device including a plurality of thin layers comprising a layer formed with a polarizable ferroelectric material according to several directions of polarization according to an electric voltage applied to said ferroelectric material layer, surrounded by a pair of conductive layers forming electrodes, comprising an intermediate layer between said layer of ferroelectric material and one of the conductive layers, said intermediate layer consisting of a material for which the electronic properties are modified according to the direction of polarization in said adjacent ferroelectric material layer.

2. The device according to claim 1, wherein said electronic properties of the intermediate layer are conductivity properties.

3. The device according to claim 1, wherein said electronic properties of the intermediate layer are band gap width properties.

4. The device according to claim 1, wherein the modification of the electronic properties of the intermediate layer is obtained by the variation of the density of carriers in said intermediate layer.

5. The device according to claim 4, it wherein said intermediate layer consists of a material having a metal-insulated transition depending on the number of carriers.

6. The device according to claim 5, wherein said intermediate layer consists of perovskite material selected from the group consisting of titanium perovskite of formula A₁₋ₓA′ₓTiO₃, wherein A and A′ are different 3+ ions, and x is between 0 and 1; titanium perovskite of formula A₁₋ₓBₓTiO₃, wherein A is a 3+ ion, B is a 2+ ion, and x is between 0 and 1; vanadium perovskite of formula A₁₋ₓBₓVO₃, wherein A is a 3+ ion, B is a 2+ ion, and x is between 0 and 1; and cobalt perovskite of formula A₁₋ₓBₓCoO₃, wherein A is a 3+ ion, B is a 2+ ion, and x is between 0 and 1.

7. The device according to claim 1, wherein the intermediate layer has a thickness that is between 0.1 nm and 10 nm.

8. A non-volatile memory comprising a memory element including a plurality of thin layers comprising a layer formed with a polarizable ferroelectric material according to several directions of polarization according to an electric voltage applied to said ferroelectric material layer, surrounded by a pair of conductive layers forming electrodes, comprising an intermediate layer between said layer of ferroelectric material and one of the conductive layers, said intermediate layer consisting of a material for which the electronic properties are modified according to the direction of polarization in said adjacent ferroelectric material layer, wherein a piece of information is written to the non-volatile memory by applying an electric voltage greater in absolute value than a threshold voltage at the ferroelectric material layer of the memory element.

9. A programmable logic circuit comprising an element including a plurality of thin layers comprising a layer formed with a polarizable ferroelectric material according to several directions of polarization according to an electric voltage applied to said ferroelectric material layer, surrounded by a pair of conductive layers forming electrodes, comprising an intermediate layer between said layer of ferroelectric material and one of the conductive layers, said intermediate layer consisting of a material for which the electronic properties are modified according to the direction of polarization in said adjacent ferroelectric material layer, wherein the device is used in the programmable logic circuit, wherein a piece of information is written into the programmable logic circuit by applying an electric voltage greater in absolute value than a threshold voltage at the ferroelectric material layer of the element.

10. A microcircuit comprising a microswitch comprising a plurality of thin layers comprising a layer formed with a polarizable ferroelectric material according to several directions of polarization according to an electric voltage applied to said ferroelectric material layer, surrounded by a pair of conductive layers forming electrodes, comprising an intermediate layer between said layer of ferroelectric material and one of the conductive layers, said intermediate layer consisting of a material for which the electronic properties are modified according to the direction of polarization in said adjacent ferroelectric material layer, wherein the device is used in the programmable logic circuit, wherein the microcircuit is closed by applying an electric voltage greater in absolute value than a threshold voltage at the ferroelectric material layer of the microswitch.
